(19) United States
(12) Patent Application Publication
(10) Pub. No.: US 2004/0190245 A1
(43) Pub. Date: Sep. 30, 2004

(54) Radial heat sink with skived-shaped fin and methods of making same

(76) Inventors: Murli Tirumala, Beaverton, OR (US); Seri Lee, Beaverton, OR (US)

Correspondence Address: SCHWEGMAN, LUNDBERG, WOESSNER & KLUTH, P.A., P.O. BOX 2938, MINNEAPOLIS, MN, 55402, US

(21) Appl. No.: 10/404,915

(22) Filed: Mar. 31, 2003

(51) Int. Cl. H05K 7/20

(52) U.S. Cl. 361/690

(57) ABSTRACT

A radial-fin heat sink includes a heat sink substrate and a radial fin that extends from the heat sink substrate. The radial fin is formed from the heat sink substrate by a skiving process.

### TECHNICAL FIELD

Disclosed embodiments relate to a radial heat transfer structure. The radial heat transfer structure includes a plurality of fins manufactured by skiving. More particularly, an embodiment relates to a radial heat transfer structure that includes a skived fin.

### BACKGROUND INFORMATION

### DESCRIPTION OF RELATED ART

Processors are often fabricated on integrated circuit (IC) dice. As a processor's performance increases, so does its power consumption. Likewise, the amount of heat generated by the processor increases when the processor is employed as part of an electronic assembly. Accordingly, a thermal interface is often needed to allow the processor to dispel heat more efficiently. Various structures have been used to allow a processor to efficiently dispel heat.

A known thermal interface may employ a heat sink such as a finned heat sink. One issue encountered when using a finned heat sink is providing sufficient surface area to meet the increased heat-transfer duty that is demanded for high performance IC devices. It is therefore desired to fabricate a finned heat sink having a greater number of fins than known finned heat sinks.

### BRIEF DESCRIPTION OF THE DRAWINGS

In order to understand the manner in which embodiments are obtained, a more particular description of various embodiments will be rendered by reference to the appended drawings. These drawings depict only typical embodiments that are not necessarily drawn to scale and are not therefore to be considered to be limiting in scope. Some embodiments of the invention will be described and explained with additional specificity and detail through the use of the accompanying drawings in which:

FIG. 1A is a perspective view of a skived structure made from rectangular bar stock;

FIG. 1B is a top-view of a skived radial-fin heat sink after arcuate deflection of the skived structure depicted in FIG. 1, according to an embodiment;

FIG. 2 is an elevational cross-section of the skived radial-finned heat sink depicted in FIG. 1B;

FIG. 3 is a detail section of a skived fin and a portion of the substrate from the skived radial-finned heat sink depicted in FIG. 1B;

FIG. 4 is a top-view of a skived radial-fin heat sink with a heat transfer core according to an embodiment;

FIG. 5A is a perspective view of a cylindrical bar stock;

FIG. 5B is a top view of a skived radial-fin heat sink taken from the cylindrical bar stock depicted in FIG. 5A according to an embodiment;

FIG. 6 is a cross-section of a skived radial-fin heat sink, taken along the line 6-6 in FIG. 5B according to an embodiment;

FIG. 7 is a top cross-section of a skived radial-fin heat sink taken from the cylindrical bar stock depicted in FIG. 5A according to an embodiment;

FIG. 8 is another a top cross-section of the skived radial-fin heat sink depicted in FIG. 7, and likewise taken from the cylindrical bar stock depicted in FIG. 5A according to an embodiment;

FIG. 9 is a cross-section of the skived radial-fin heat sink depicted in various cross-sectional top views in FIGS. 7 and 8 according to an embodiment;

FIG. 10A is a perspective view of a truncated conical bar stock;

FIG. 10B is a top view of a skived radial-fin heat sink fabricated from the cylindrical bar stock depicted in FIG. 10A according to an embodiment;

FIG. 11A is a cross-section of a skived radial-fin heat sink, taken along the section line 11-11 in FIG. 10B according to an embodiment;

FIG. 11B is a cross-section of a skived radial-fin heat sink according to an embodiment;

FIG. 12 is an elevational cross-section of a packaging system according to an embodiment;

FIG. 13 is an elevational cross-section of a packaging system according to an embodiment;

FIG. 14 is a method flow diagram that depicts non-limiting method embodiments;

FIG. 15 is a depiction of a computing system; and

FIG. 16 is a top-view of a skived radial-fin heat sink 1600 after arcuate deflection of a skived structure according to an embodiment.

### DETAILED DESCRIPTION

The following description includes terms such as upper, lower, first, second, etc. that are used for descriptive purposes only, and they are not to be construed as limiting. The embodiments of a device or article described herein can be manufactured, used, or shipped in a number of positions and orientations.

Reference will now be made to the drawings wherein like structures will be provided with like reference designations. In order to show the structures of embodiments most clearly, the drawings included herein are diagrammatic representations of inventive articles. Thus, the actual appearance of the fabricated structures, for example in a photomicrograph, may appear different while still incorporating the essential structures of embodiments. Moreover, the drawings show only the structures necessary to understand the embodiments. Additional structures known in the art have not been included to maintain the clarity of the drawings.

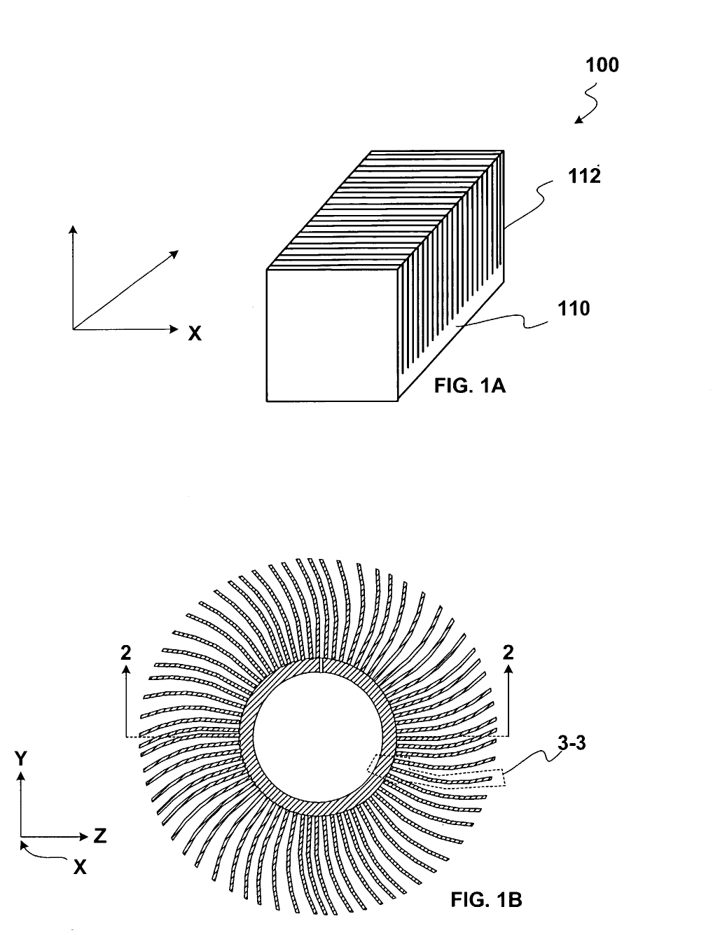

FIG. 1A is a perspective view of a skived structure 100 made from rectangular bar stock. A skived structure 100 includes a base 110 and a plurality of skived fins 112 that have been cut into a stock piece such as rectangular bar stock. Only the X-dimension is assigned in FIG. 1A to facilitate further disclosure.

FIG. 1B is a top-view of a skived radial-fin heat sink 101 after arcuate deflection of the skived structure 100 depicted in FIG. 1, according to an embodiment. The skived structure 100 (FIG. 1A) has been reconfigured to create a radial-fin heat sink 101. The radial-fin heat sink 101 includes a heat sink substrate 111 that is the base 110 depicted in FIG. 1A.

In one embodiment, the heat sink substrate 111 is fused at a joint 114 by a suitable process such as soldering, welding, and melting of the heat sink substrate 111. FIG. 1B also illustrates the preservation of the X-axis as depicted in FIG. 1A. Because the base 110 in FIG. 1A has been transformed into the heat sink substrate 111 by a process that causes an arcuate deflection of the base 110, the only reference dimension from FIG. 1A is the X-axis, as depicted coming out of the plane of the page in FIG. 1B. Because, in this embodiment, the radial-fin heat sink 101 has substantial radial symmetry, the particular new axes, Y and Z, are given in FIG. 1B for illustrative purposes.

The term “suitable”, as used herein, means having characteristics that are sufficient to produce the desired result(s). Suitability for the intended purpose can be determined by one of ordinary skill in the art using only routine experimentation.

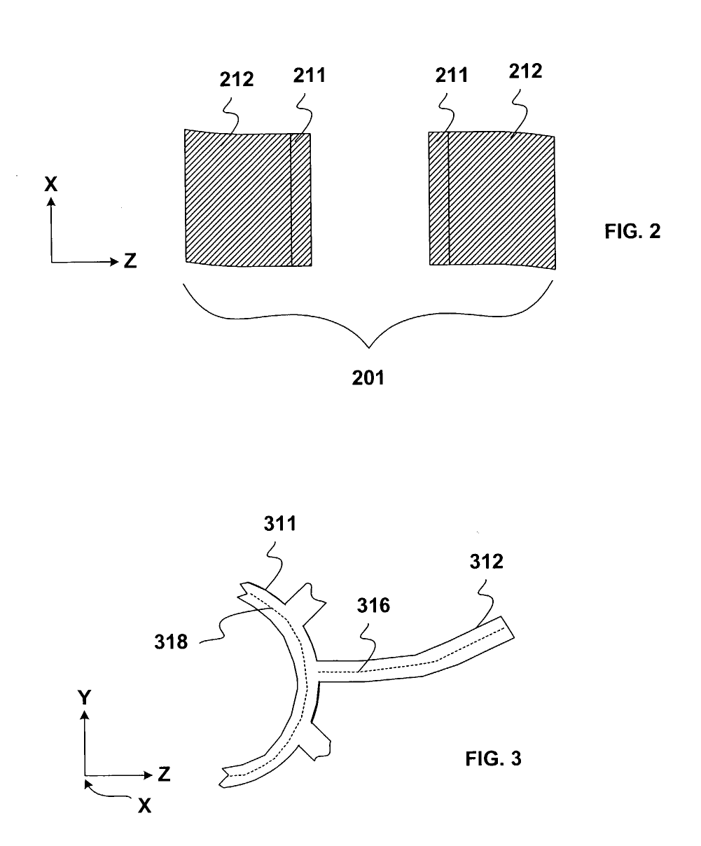

FIG. 2 is an elevational cross-section of the skived radial-fin heat sink 101 depicted in FIG. 1B. FIG. 2 is a view taken from the line 2-2, depicted in FIG. 1B. The radial-fin heat sink 201 is depicted with the X-axis as a vertical dimension, and the Z-axis as a lateral dimension. FIG. 2 depicts a skived fin 212 as an integral part of the heat sink substrate 211.

FIG. 3 is a detail section of a skived fin 312 and a portion of the substrate 311 from the skived radial-fin heat sink 101 depicted in FIG. 1B. FIG. 3 is taken from the section 3 depicted in FIG. 1B. FIG. 3 is a simplified schematic of the portion taken in the section line for illustrative purposes. Again, in FIG. 3, the Y-dimension passes out of the plane of the figure, from the skived structure 100 depicted in FIG. 1A, and the Z and X axes define dimensions within the plane of the figure.

In one embodiment, the process of skiving involves employing a sharp cutting blade to carry out a thin slicing or shaving operation without causing the shaving to fragment from the stock material. A radial fin, such as the skived fin 312 depicted in FIG. 3, exhibits an arcuate deflection due to the skiving process. In one embodiment, wherein the skived structure 300 is a metal, the skived fin 312 can be examined under a photomicroscope, and it can be observed that along a fin symmetry line 316 the metallic grain structure exhibits a composition structure that is characteristic of the arcuate deflection caused by the skiving process. This arcuate deflection composition structure can be contrasted to the metallography that is observable in a curved fin that has been formed through an extrusion process.

The heat sink substrate 311 likewise has a substrate symmetry line 318. Because the heat sink substrate 311 has also been deflected into an arcuate configuration, the heat sink substrate 311 includes a composition structure characteristic of arcuate deflection. This characteristic arcuate deflection can be detected, for example, when the skived structure such as the radial-fin heat sink 101 (FIG. 1B) is a metal, by the observation of metal grains that are aligned symmetrically about the substrate symmetry line 318. This arcuate deflection composition structure can be contrasted to the metallography that is observable in an extruded radial-fin heat sink, which exhibits a substrate composition structure characteristic of an extrusion process.

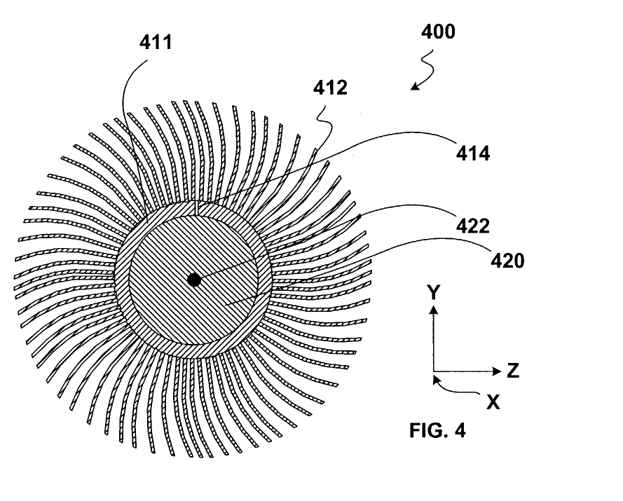

FIG. 4 is a top view of a skived radial-fin heat sink 400 with a heat transfer core 420 according to an embodiment. A radial-fin heat sink 400, similar to the radial-fin heat sink 110 depicted in FIG. 1B, includes a plurality of skived fins 412, a heat sink substrate 411, and a joint 414. Additionally, a heat-transfer core 420 is depicted as being disposed about a radial centerline 422 that is perpendicular to the plane of FIG. 4. In one embodiment, the heat-transfer core 420 is a metal. In one embodiment, the heat-transfer core 420 is a metal including copper, or a copper alloy. In one embodiment, the heat-transfer core 420 is a metal including aluminum, or an aluminum alloy. In one embodiment, the heat-transfer core 420 is an inorganic composite including a ceramic, a metal-infiltrated ceramic, or the like. In one embodiment, the heat-transfer core 420 is an organic/inorganic composite including a resin/graphite composite or the like.

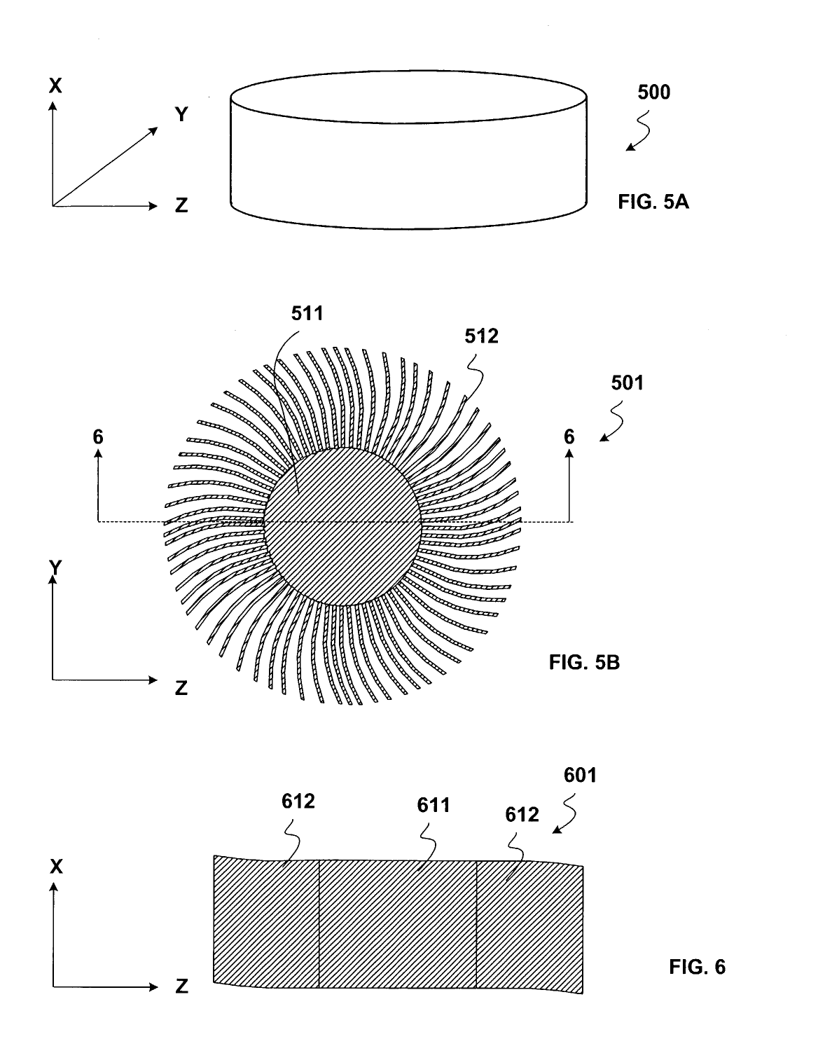

FIG. 5A is a perspective view of a cylindrical bar stock 500. FIG. 5A illustrates cylindrical bar stock 500 that is to be subjected to a skiving process to form a radial-fin heat sink. By contrast, the skived structure 100 in FIG. 1A was skived from a rectangular bar stock. Similar to the rectangular bar stock from which the skived structure 100 was formed, the cylindrical bar stock 500 can be a material such as a metal or an inorganic/organic composite.

FIG. 5B is a top-view of a skived radial-fin heat sink 501 taken from the cylindrical bar stock 500 depicted in FIG. 5A according to an embodiment. After the skiving process has been carried out on the cylindrical bar stock 500, a radial-fin heat sink 501 has been fabricated. A plurality of skived fins 512 have been cut into the cylindrical bar stock 500 (FIG. 5A) to a given depth to form the plurality of skived fins 512. A heat-sink substrate 511 is depicted as the unskived portion of the cylindrical bar stock 500. Accordingly, any skived fin 512 and the heat sink substrate 511 are an integral structure that has been formed from the cylindrical bar stock 500.

FIG. 6 is a cross-section of a skived radial-fin heat sink 601, taken along the section line 6-6 in FIG. 5B according to an embodiment. The radial-fin heat sink 601 in FIG. 6 depicts in substantial cross-section the radial-fin heat sink 501 that was fabricated from the cylindrical bar stock 500. FIG. 6 depicts substantially rectangular skived fins 612 and a substrate 610. In one embodiment, the substantially rectangular skived fins 612 that were formed during the skiving process were skived with a cutting implement that remains substantially parallel to the X-axis for the two skived fins 612 depicted.

In an alternative embodiment, a radial-fin heat sink structure with a heat transfer core is fabricated. The radial-fin heat sink structure is fabricated from the radial-fin heat sink 501 depicted in FIG. 5B. Accordingly, a substantial portion of the heat sink substrate 511 is bored out, and a heat-transfer core similar to the heat-transfer core 420 (FIG. 4) is inserted. In this embodiment, the requirement to arcuately deflect a skived structure such as the substrate 110 depicted in FIG. 1A is avoided.

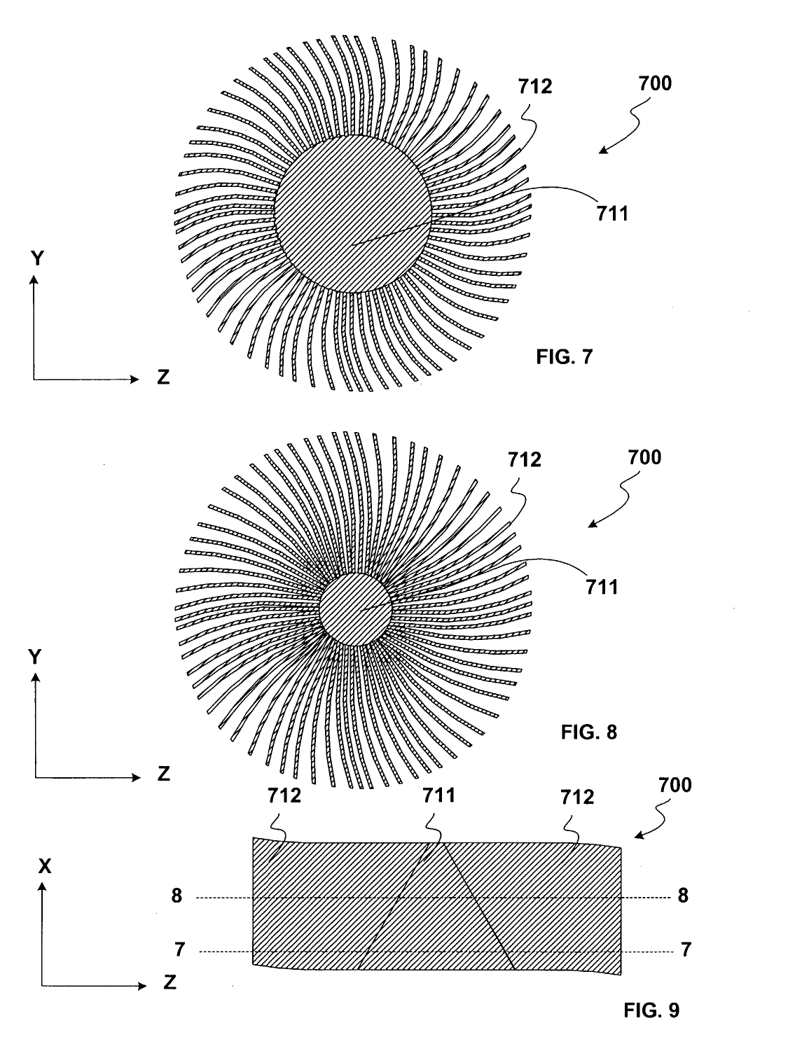

FIG. 7 is a top cross-section of a skived radial-fin heat sink 700 taken from the cylindrical bar stock depicted in FIG. 5A according to an embodiment. FIG. 7 depicts a radial-fin heat sink 700 that has been fabricated from cylindrical bar stock 500. The radial-fin heat sink 700 includes a plurality of skived fins 712 and a heat sink substrate 711. The radial-fin heat sink 700 is taken in a cross-section near the base thereof.

FIG. 8 is another top cross-section of the skived radial-fin heat sink 700 depicted in FIG. 7, and likewise taken from the cylindrical bar stock 500 depicted in FIG. 5A according to an embodiment. The radial-fin heat sink 700 depicted in FIG. 8 is taken from a cross-section that is above the view taken in FIG. 7. The radial-fin heat sink 700 includes the same plurality of skived fins 712 and the heat sink substrate 711. It is noted that the heat sink substrate 711 has a smaller diameter in the view depicted in FIG. 8 than in the view depicted in FIG. 7.

FIG. 9 is a cross-section of the skived radial-fin heat sink 700 depicted in the cross-sectional views in FIGS. 7 and 8 according to an embodiment. The radial-fin heat sink 700 illustrates the result of a skiving process. In this embodiment, the skiving implement has formed the plurality of skived fins 712 by cutting at an angle that is non-parallel and not orthogonal to the Z-axis. Consequently, the shape of each skived fin 712 is a trapezoid. In one embodiment, heat transfer is selected to be greater than a rectangular skived fin can provide, such as the skived fin 112 depicted in FIG. 2. Therefore, a radial-fin heat sink such as the radial-fin heat sink 700, depicted in FIG. 9, provides a larger surface area of the skived fin 712 at a higher location in comparison to a smaller surface area at a lower location near the bottom of the radial-fin heat sink 700. Because the heat sink substrate 711 also is a non-rectangular shape, such as an isosceles trapezoid, heat transfer is improved by conduction near the bottom of the heat sink substrate 711, but is exchanged more efficient convection by passing a fluid across the plurality of skived fins 712.

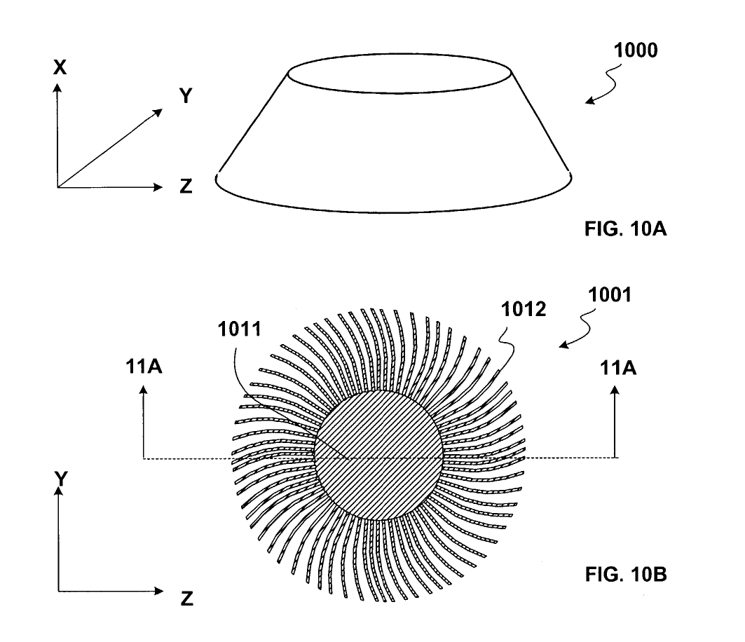

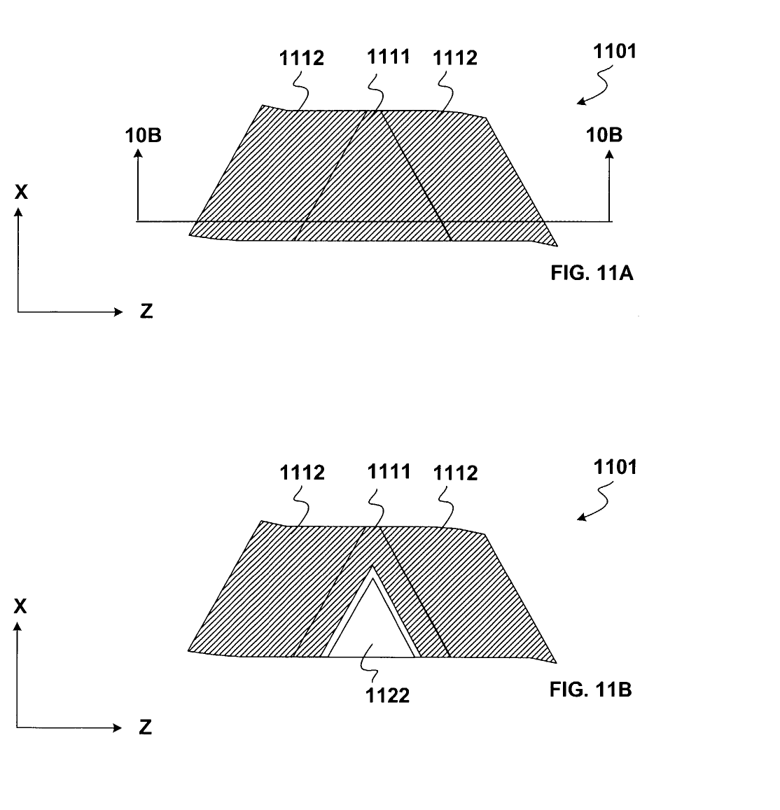

FIG. 10A is a perspective view of a truncated conical bar stock 1000. A truncated conical bar stock 1000 is a precursor structure for another embodiment. FIG. 10B is a top-view of a skived radial-fin heat sink 1001 fabricated from the truncated conical bar stock 1000 depicted in FIG. 10A according to an embodiment. A plurality of skived fins 1012 have been cut out of the truncated conical bar stock 1000 to form the radial-fin heat sink 1001. A heat sink substrate 1011 is the uncut portion of the truncated conical bar stock 1000.

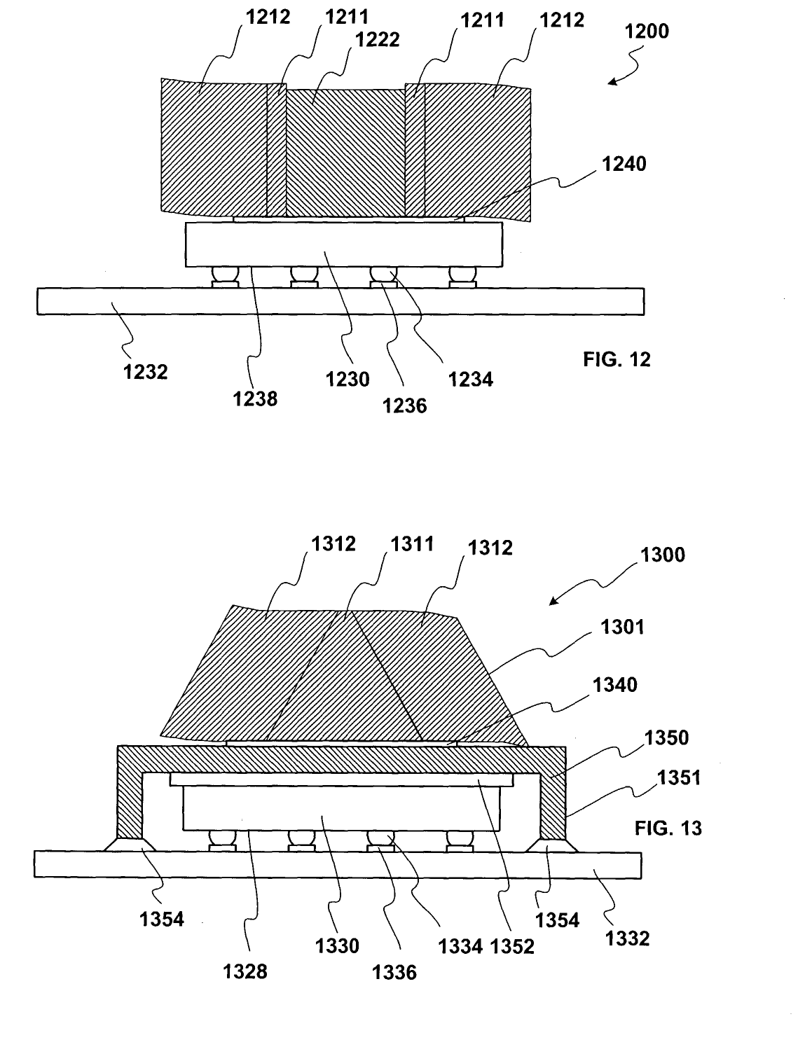

FIG. 11A is a cross-section of a skived radial-fin heat sink 1101, taken along the section line 11-11 in FIG. 10B according to an embodiment. In cross-section view, the radial-fin heat sink 1101 depicts the plurality of skived fins 1112 as having a substantial parallelogram shape. The radial-fin heat sink 1101 also depicts a substrate 1111. This parallelogram shape for the skived fins 1112 is achieved by applying the skiving implement substantially parallel to the exterior walls of the truncated conical bar stock 1000 (FIG. 10A) during the skiving process.

FIG. 11B is a cross-section of a skived radial-fin heat sink 1101 according to an embodiment. The skived radial-fin heat sink 1101 has been further processed, based upon a skived radial-fin heat sink 1101 depicted in FIG. 11A according to an embodiment. In one embodiment, a heat-transfer core 1122 has a conical shape. The heat transfer core 1122 is formed by boring into the heat sink substrate 1111 after the formation of the plurality of skived fins 1112. In one embodiment, a heat-transfer core that is substantially right-cylindrical (not pictured), can also be formed in the heat sink substrate 1111 depicted in FIG. 11B.

FIG. 12 is an elevational cross-section of a packaging system 1200 according to an embodiment. The packaging system 1200 includes radial-fin heat sink 1201 that includes a plurality of skived fins 1212 and a heat sink substrate 1211. In one embodiment, the radial-fin heat sink 1201 includes a heat transfer core 1222 according to the various embodiments set forth in this disclosure. The packaging system 1200 also includes a die 1230. The die 1230 is depicted as being attached to a mounting substrate 1232. The mounting substrate 1232 comprises a board such as a main board, an expansion card, a mezzanine board, and the like. The die 1230 may be mounted onto the mounting substrate 1232 through a series of electrical bumps 1234 that are in turn each mounted on a series of bond pads 1236. The electrical bumps 1234 make contact with the active surface 1238 of the die 1230.

In one embodiment, the radial-fin heat sink 1201 and the die 1230 are secured together and maintained in thermal contact with one another by an adhesive layer 1240 as is known in the art. In one embodiment, the adhesive layer 1240 comprises a solder that has a coefficient of thermal expansion (CTE) that is between the CTE of the radial-fin heat sink 1201 and the die 1230. In one embodiment, the adhesive layer 1240 comprises an organic substance that likewise has a CTE that is between the CTE of the radial-fin heat sink 1201 and the die 1230.

The embodiment depicted in FIG. 12 can be changed by substituting any of the disclosed radial-fin heat sinks in place of the radial-fin heat sink 1201 depicted in FIG. 12.

FIG. 13 is an elevational cross-section of a packaging system 1300 according to an embodiment. FIG. 13 depicts a packaging system 1300 including a radial-fin heat sink 1301 that is similar to the radial-fin heat sink 1101 depicted in FIG. 11. The radial-fin heat sink 1301 includes a skived fin 1312 and a heat sink substrate 1311.

A die 1330 including an active surface 1328, is disposed below the radial-fin heat sink 1301. An integrated heat spreader (IHS) 1350 is disposed between the radial-fin heat sink 1301 and the die 1330. An adhesive layer 1340 secures the radial-fin heat sink 1301 to the IHS 1350. An IHS adhesive layer 1352 may secure the die 1330 to the IHS 1350. Similar to the depiction in FIG. 12, the die 1330 may be coupled to a mounting substrate 1332 through a series of electrical bumps 1334 that are mounted on a series of bond pads 1336 that are disposed upon the mounting substrate 1332.

In one embodiment, the IHS 1350 includes a lip portion 1351 that likewise is mounted on the mounting substrate 1332 by mounting substrate adhesive 1354.

In the embodiment depicted in FIG. 13, as in the embodiment depicted in FIG. 12, any of the disclosed radial-fin heat sinks may be substituted for the radial-fin heat sink 1301.

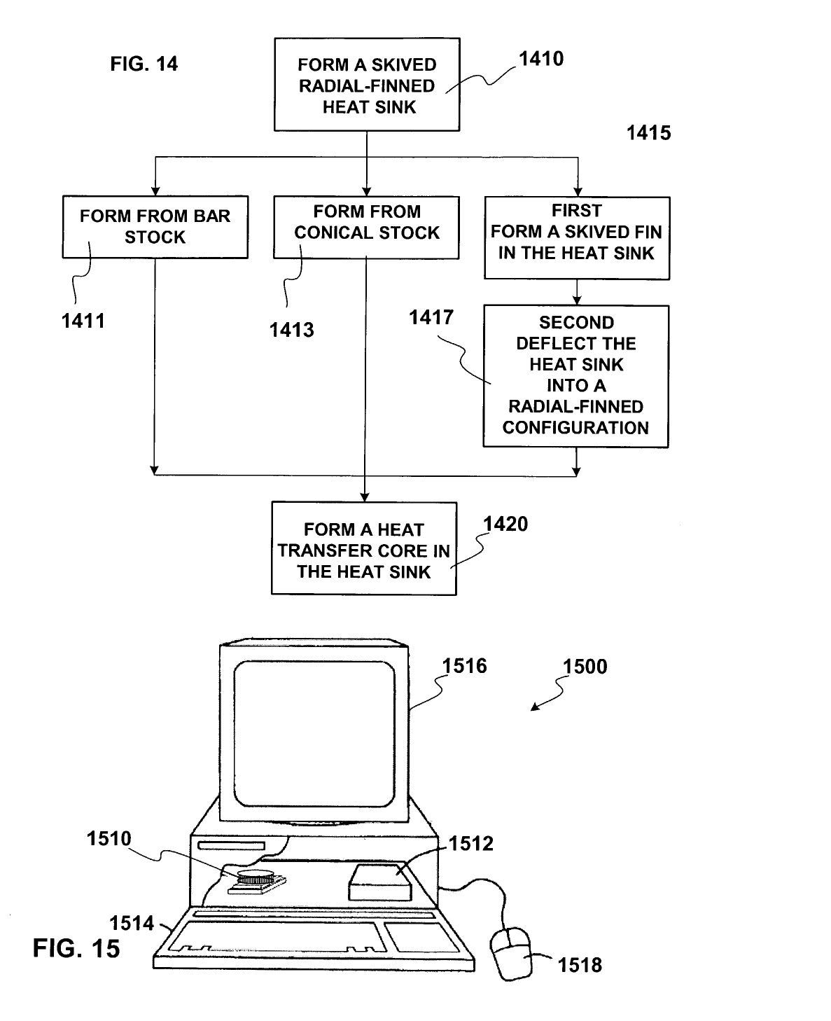

FIG. 14 is a method flow diagram that depicts non-limiting method embodiments. The process 1410 includes forming a skived radial-fin heat sink according to various embodiments disclosed herein, corresponding to 1411, 1413, and 1415, respectively. At 1411, a skived radial-fin heat sink is formed from bar stock. At 1413, a skived radial-fin heat sink is formed from conical stock. At 1415, a skived fin is first formed in a heat sink, and the heat sink is then deflected into a skived radial-fin heat sink.

At 1420, a heat transfer core is optionally formed in the heat sink.

FIG. 15 is a depiction of a computing system. One or more of the foregoing embodiments of a package with a skived-fin heat sink may be utilized in a computing system, such as a computing system 1500 of FIG. 15. The computing system 1500 includes at least one processor (not pictured) under a skived-fin heat sink 1510, a data storage system 1512, at least one input device such as keyboard 1514, and at least one output device such as monitor 1516, for example. The computing system 1500 includes a processor that processes data signals, and may comprise, for example, a PENTIUM®III or PENTIUM® 4 microprocessor, available from Intel® Corporation. In addition to the keyboard 1514, the computing system 1500 can include another user input device such as a mouse 1518, for example. The computing system 1500 may utilize one or more microelectronic packages such as described in one or more of the foregoing embodiments. For purposes of this application, a computing system 1500 embodying components in accordance with the claimed subject matter may include any system that utilizes a skived-fin heat sink, which may include, for example, a data storage device such as dynamic random access memory, polymer memory, flash memory, and phase-change memory. The package can also include a die which contains a digital signal processor (DSP), a micro controller, an application specific integrated circuit (ASIC), or a microprocessor. It can now be appreciated that embodiments set forth in this disclosure can be applied to devices and apparatuses other than a traditional computer. For example, a die can be packaged with an embodiment of the skived-fin heat sink and placed in a portable device such as a wireless communicator or a hand-held such as a personal data assistant and the like. Another example is a die which can be packaged with an embodiment of the skived-fin heat sink and placed in a vehicle such as an automobile, a locomotive, a watercraft, an aircraft, or a spacecraft.

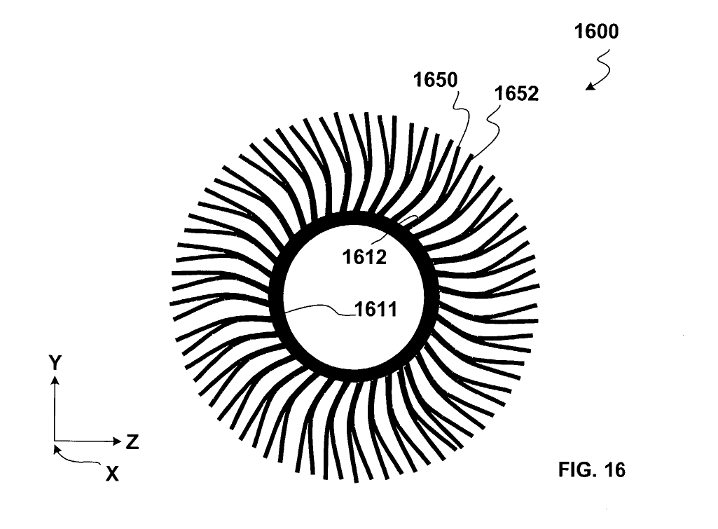

FIG. 16 is a top-view of a skived radial-fin heat sink 1600 after arcuate deflection of a skived structure according to an embodiment. In this embodiment, a multiple-skived fin 1612 was fabricated. The skived radial-fin heat sink 1600 includes a heat sink substrate 1611. In one embodiment, the multiple-skived fin 1612 is fabricated by cutting a first-skived fin 1650 along a significant depth fraction of the multiple-skived fin 1612, followed by a subsequent-skived fin 1652, which is skived to the depth of the heat sink substrate 1611. According to this embodiment, the multiple-skived fin increases total fin surface area by forming split fin tips on a multiple-skived fin 1612. The multiple-skived fin 1612 increases the surface area while improves the performance by distributing the air flow evenly along the fin gaps with and even longitudinal pressure drop.

It is emphasized that the Abstract is provided to comply with 37 C.F.R. § 1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this subject matter may be made without departing from the principles and scope of the subject matter as expressed in the subjoined claims.

What is claimed is:

1. A radial-fin heat sink comprising:
a substrate; and
a radial fin extending from the substrate, wherein the radial fin includes a composition structure characteristic of arcuate deflection.

2. The radial-fin heat sink according to claim 1, wherein the substrate includes a composition structure characteristic of arcuate deflection.

3. The radial-fin heat sink according to claim 1, wherein the substrate is selected from a cylinder, a cone, and a truncated cone.

4. The radial-fin heat sink according to claim 1, wherein the substrate is selected from a hollow cylinder, a hollow cone, and a hollow truncated cone.

5. The radial-fin heat sink according to claim 1, wherein the substrate further includes:
a heat-transfer core, wherein the heat-transfer core is at a substantial radial center line of the radial-fin heat sink.

6. The radial-fin heat sink according to claim 1, wherein the substrate further includes:
a heat-transfer core, wherein the heat transfer core is disposed at a substantial radial center line of the radial-fin heat sink, wherein the heat-transfer core is selected from a metal, an inorganic composite, an organic composite, and an organic/inorganic composite.

7. The radial-fin heat sink according to claim 1, wherein the radial-fin heat sink includes a material selected from a metal, copper, a copper alloy, aluminum, an aluminum alloy, an inorganic composite, an organic/inorganic composite, a resin/graphite composite, and combinations thereof.

8. The radial-fin heat sink according to claim 1, wherein the radial-fin heat sink includes a material selected from a metal, copper, a copper alloy, aluminum, an aluminum alloy, an inorganic composite, an organic/inorganic composite, a resin/graphite composite, and combinations thereof, and wherein the substrate further includes:
a heat-transfer core.

9. The radial-fin heat sink according to claim 1, wherein the radial-fin heat sink includes a material selected from a metal, copper, a copper alloy, aluminum, an aluminum alloy, an inorganic composite, an organic/inorganic composite, a resin/graphite composite, and combinations thereof, and wherein the substrate further includes:
a heat-transfer core, wherein the heat-transfer core is selected from a metal, an inorganic composite, an organic composite, and an organic/inorganic composite.

10. The radial-fin heat sink according to claim 1, wherein the radial fin is a multiple-skived fin.

11. A packaging system comprising:
a die including a surface; and
a heat sink including a radial fin in thermal contact with the surface, wherein the radial fin includes a composition structure characteristic of arcuate deflection.

12. The packaging system according to claim 11, the heat sink further including:
a substrate, wherein the substrate includes a composition structure characteristic of arcuate deflection.

13. The packaging system according to claim 11, the heat sink further including:
a substrate, wherein the substrate includes a composition structure characteristic of arcuate deflection; and
a heat transfer core.

14. The packaging system according to claim 11, the system further including:
a heat spreader disposed between the die surface and the heat sink.

15. The packaging system according to claim 11, wherein the substrate is selected from a cylinder, a cone, and a truncated cone.

16. The packaging system according to claim 11, wherein the substrate is selected from a hollow cylinder, a hollow cone, and a hollow truncated cone.

17. The packaging system according to claim 11, wherein the substrate further includes:
a heat-transfer core, wherein the heat-transfer core is selected from a metal, an inorganic composite, an organic composite, and an organic/inorganic composite.

18. The packaging system according to claim 11, wherein the die includes a processor.

19. A process comprising:
forming a radial-fin heat sink by skiving a fin.

20. The process according to claim 19, the radial-fin heat sink further including a substrate, the process further including:
forming the substrate into an arcuate configuration.

21. The process according to claim 19, the radial-fin heat sink further including a substrate, wherein skiving a fin is selected from skiving a fin from cylindrical bar stock, skiving a fin from rectangular bar stock, and skiving a fin from conical bar stock.

22. The process according to claim 19, wherein skiving a fin further includes:
skiving a fin that includes a shape selected from a rectangle, a parallelogram, and a trapezoid.

23. The process according to claim 19, further including:
forming a heat transfer core in the substrate.

24. The process according to claim 19, wherein forming a radial-fin heat sink by skiving a fin includes multiple-skiving a fin.

25. A method comprising:
forming an assembly including a substrate, a die coupled to the substrate, and a skived radial-fin heat sink in thermal contact with the die.

26. The method according to claim 25, further including:
installing the assembly into a computing system.
